(19) United States
(12) Patent Application Publication
(10) Pub. No.: US 2016/0049821 A1
(43) Pub. Date: Feb. 18, 2016

(54) ELECTRICAL STORAGE SYSTEM, AND FULL CHARGE CAPACITY ESTIMATION METHOD FOR ELECTRICAL STORAGE DEVICE

(71) Applicant: Koji ARIDOME, (US)

(72) Inventor: Koji ARIDOME, Toyota-shi, Aichi-ken (JP)

(73) Assignee: TOYOTA JIDOSHA KABUSHIKI KAISHA, Toyota-shi, Aichi-ken (JP)

(21) Appl. No.: 14/778,772

(22) PCT Filed: Mar. 17, 2014
(86) PCT No.: PCT/IB2014/000443

§ 371 Date: Sep. 21, 2015

(30) Foreign Application Priority Data
Mar. 22, 2013 (JP) 2013-059904

(51) Int. Cl. H02J 7/00; H01M 10/48; G01R 31/36; H01M 10/44

(52) U.S. Cl. CPC H02J 7/0068; H01M 10/44; H01M 10/48; G01R 31/3624; G01R 31/3648; H01M 2010/4271

(57) ABSTRACT

An electrical storage system mounted on a vehicle includes: an electrical storage device that is charged or discharged; and a controller that calculates an SOC on the basis of a correspondence relationship between a voltage of the electrical storage device and an SOC of the electrical storage device and that calculates a full charge capacity of the electrical storage device on the basis of an SOC difference between before and after charging and an accumulated charging current value during charging.

### BACKGROUND OF THE INVENTION

1. Field of the Invention

The invention relates to a technique for estimating a full charge capacity of a secondary battery, or the like.

2. Description of Related Art

A state of charge (SOC) indicates the percentage of a current charge amount to a full charge capacity. The full charge capacity is, for example, allowed to be calculated on the basis of an SOC difference, which is calculated from the terminal voltage (OCV) of a battery before charging and the terminal voltage of the battery after charging, and an accumulated current value during charging (for example, Japanese Patent Application Publication No. 2012-29455 (JP 2012-29455 A)).

The SOC and the OCV are in a correspondence relationship, so it is possible to calculate a current SOC of the battery on the basis of a voltage value that is detected by a voltage sensor if the correspondence relationship is obtained in advance.

However, the correspondence relationship between the SOC and the OCV has a region in which a change in OCV is small for a change in SOC. In that region, the OCV does not change so much even when the SOC changes, so the accuracy of calculating (estimating) the SOC decreases. In other words, in a region in which a change in SOC is large for a change in OCV, it may not be able to accurately calculate the SOC because of variations due to a detection error, or the like, of the voltage sensor.

### SUMMARY OF THE INVENTION

The invention provides an electrical storage system and a full charge capacity estimation method for an electrical storage device, which accurately calculate a full charge capacity by improving the accuracy of calculating an initial SOC that is acquired at the start of charging for full charge capacity.

A first aspect of the invention provides an electrical storage system mounted on a vehicle. The electrical storage system includes: an electrical storage device configured to be charged or discharged; and a controller configured to calculate an SOC on the basis of a correspondence relationship between a voltage of the electrical storage device and an SOC of the electrical storage device, the controller being configured to calculate a full charge capacity of the electrical storage device on the basis of an SOC difference between before and after charging and an accumulated charging current value during charging.

When a first SOC that is calculated at start of charging is an SOC corresponding to a region in which a rate of change in voltage for a change in SOC is smaller than a predetermined value in the correspondence relationship, the controller is configured to execute control for charging the electrical storage device until the SOC of the electrical storage device changes from the first SOC to a second SOC corresponding to a region in which the rate of change in voltage for a change in SOC is larger than the predetermined value. The controller is configured to calculate the full charge capacity on the basis of an accumulated charging current value from a state where the electrical storage device has been charged to the second SOC to termination of charging and an SOC difference between the second SOC and a third SOC that is calculated at the termination of charging.

According to the first aspect of the invention, the SOC is calculated at the timing at which accumulation of the accumulated charging current value for calculating, the full charge capacity is started by avoiding calculation of the SOC in the region in which a change in voltage for a change in SOC is small. Therefore, the accuracy of calculating the SOC improves, and it is possible to accurately calculate the full charge capacity.

When the first SOC is the SOC corresponding to the region in which the rate of change in voltage for a change in SOC is larger than the predetermined value, the controller may be configured to calculate the full charge capacity on the basis of an accumulated charging current value from a state of the first SOC to the termination of charging and an SOC difference between the first SOC and the third SOC. With such a configuration, when it is not in the case of calculating the SOC in the region in which a change in voltage for a change in SOC is small, it is determined that it is possible to accurately calculate the SOC for calculating the full charge capacity, so it is possible to quickly calculate a highly accurate full charge capacity.

When the first SOC is the SOC corresponding to the region in which the rate of change in voltage for a change in SOC is smaller than the predetermined value, the controller may be configured to execute control for charging the electrical storage device until the SOC of the electrical storage device changes to an SOC corresponding to the maximum rate of change in the region in which the rate of change in voltage for a change in SOC is larger than the predetermined value, which is adjacent to the region in which the rate of change in voltage for a change in SOC is smaller than the predetermined value. With such a configuration, it is possible to further increase the SOC calculation accuracy, and it is possible to further accurately calculate the full charge capacity.

When the first SOC is the SOC corresponding to the region in which the rate of change in voltage for a change in SOC is smaller than the predetermined value, the controller may be configured to execute control for temporarily stopping charging after the electrical storage device has been charged until the SOC of the electrical storage device changes from the first SOC to the SOC corresponding to the region in which the rate of change in voltage for a change in SOC is larger than the predetermined value, and the controller may be configured to calculate the second SOC after a lapse of a predetermined period of time from the temporary stop. With such a configuration, for example, it is possible to resolve polarization due to charging when the SOC of the electrical storage device changes from the first SOC to the SOC corresponding to the region in which the rate of change is larger than the predetermined value, so it is possible to further improve the accuracy of calculating the second SOC.

The controller may be configured to learn the full charge capacity each time of charging, and may be configured to calculate a new full charge capacity learning value by incorporating the full charge capacity in a previously calculated full charge capacity learning value. At this time, the controller may be configured to change an amount of incorporation of the full charge capacity that is incorporated in the new full charge capacity learning value, on the basis of the SOC of the electrical storage device at start of accumulating the accumulated charging current value. With such a configuration, the accuracy of calculating the full charge capacity is determined on the basis of a rate of change in voltage for a change in SOC, the amount of incorporation in the full charge capacity learning value is increased when the calculation accuracy is high, and the amount of incorporation is reduced when the calculation accuracy is low, thus making it possible to improve the accuracy of calculating the full charge capacity learning value.

A second aspect of the invention provides a full charge capacity calculation method for an electrical storage device mounted on a vehicle. The method includes: calculating each of an SOC before charging and an SOC after charging on the basis of a voltage of the electrical storage device and an SOC of the electrical storage device, and calculating an accumulated charging current value during charging; calculating a full charge capacity on the basis of an SOC difference between before and after charging and the accumulated charging current value; calculating a first SOC at start of charging at the time of calculating each of an SOC before charging and an SOC after charging on the basis of a voltage of the electrical storage device and an SOC of the electrical storage device, and calculating an accumulated charging current value during charging; when the first SOC is an SOC corresponding to a region in which a rate of change in voltage for a change in SOC is smaller than a predetermined value in the correspondence relationship, charging the electrical storage device until the SOC of the electrical storage device changes from the first SOC to a second SOC corresponding to a region in which the rate of change in voltage for a change in SOC is larger than the predetermined value; and calculating the full charge capacity on the basis of the accumulated charging current value from a state where the electrical storage device has been charged to the second SOC to termination of charging and an SOC difference between the second SOC and a third SOC that is calculated at the termination of charging. According to the second aspect of the invention, similar advantageous effects to those of the first aspect of the invention are obtained.

A third aspect of the invention provides an electrical storage system mounted on a vehicle. The electrical storage system includes: an electrical storage device configured to be charged or discharged; and a controller configured to calculate a full charge capacity of the electrical storage device on the basis of an SOC difference between before and after charging and an accumulated charging current value during charging, the controller being configured to learn the full charge capacity each time of charging and to calculate a new full charge capacity learning value by incorporating the calculated full charge capacity in a previously calculated full charge capacity learning value. The controller is configured to change an amount of incorporation of the full charge capacity that is incorporated in the new full charge capacity learning value on the basis of a rate of change corresponding to an SOC that is used as an initial SOC of the SOC difference between before and after charging and the rate of change in voltage for a change in SOC in a correspondence relationship between a voltage of the electrical storage device and an SOC of the electrical storage device, which is used to calculate the SOC of the electrical storage device.

According to the third aspect of the invention, the accuracy of calculating the SOC decreases when the rate of change in voltage for a change in SOC in the correspondence relationship between the voltage and SOC of the electrical storage device is small. Therefore, the amount of incorporation of the calculated full charge capacity that is incorporated in the new full charge capacity learning value is changed on the basis of the rate of change in voltage for a change in SOC in the correspondence relationship at the initial SOC that is used to calculate the full charge capacity, so it is possible to accurately calculate the full charge capacity learning value. For example, the amount of incorporation is reduced such that the accuracy of the full charge capacity that is incorporated in the full charge capacity learning value is low as the rate of change in the correspondence relationship at the initial SOC reduces, and the amount of incorporation is increased such that the accuracy of the full charge capacity that is incorporated in the full charge capacity learning value is high as the rate of change increases. Thus, it is possible to accurately calculate the full charge capacity learning value.

### BRIEF DESCRIPTION OF THE DRAWINGS

Features, advantages, and technical and industrial significance of exemplary embodiments of the invention will be described below with reference to the accompanying drawings, in which like numerals denote like elements, and wherein:

FIG. 1 is a view that shows the configuration of a battery system;

FIG. 2 is a graph that shows an example of the correspondence relationship between an OCV and an SOC and the slope of an OCV curve;

FIG. 3 is a graph that illustrates changing an initial SOC for calculating a full charge capacity with respect to the slope of the OCV curve in the correspondence relationship between an OCV and an SOC;

FIG. 4 is a graph that illustrates an example of charging control when the initial SOC is configured to be variable;

FIG. 5 is a flowchart that shows the charging operation of the battery system with the use of an external power supply;

FIG. 6 is a flowchart of the process of computing a full charge capacity and a full charge capacity learning value;

FIG. 7 is a graph that shows an example of calculating a reflection coefficient that is used to calculate the full charge capacity learning value; and

FIG. 8 is a flowchart that shows the charging operation of a battery system with the use of an external power supply and the process of computing a full charge capacity and a full charge capacity learning value according to an alternative embodiment.

### DETAILED DESCRIPTION OF EMBODIMENTS

Hereinafter, an embodiment of the invention will be described.

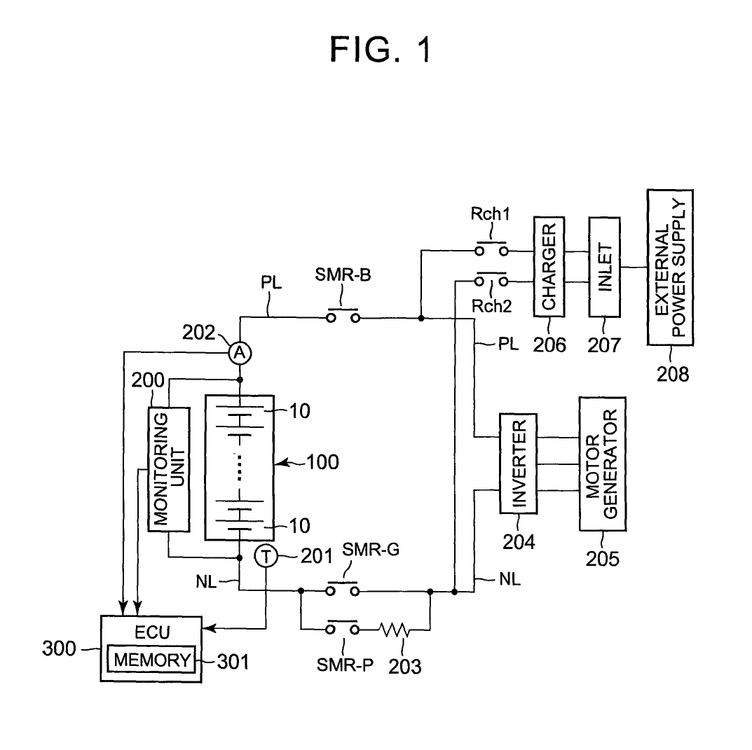

FIG. 1 is a view that shows the configuration of a battery system according to the embodiment. The battery system shown in FIG. 1 may be, for example, mounted on a vehicle. The vehicle may be, for example, a plug-in hybrid vehicle (PHV) or an electric vehicle (EV).

The PHV includes a battery pack (described later) and another power source, such as an engine and a fuel cell, as power sources for propelling the vehicle. In the PHV, the battery pack is able to be charged with electric power from an external power supply. In addition, in the PHV including an engine, by converting kinetic energy generated by the engine to electric energy, the battery pack is able to be charged with the electric energy.

The EV includes only a battery pack as a power source of the vehicle, and is able to charge the battery pack with electric power supplied from an external power supply. The external power supply is a power supply (for example, commercial power supply) installed separately from the vehicle outside the vehicle.

A battery pack (which corresponds to an electrical storage device) 100 includes a plurality of single cells (which correspond to electrical storage elements) 10 connected in series with one another. Each single cell 10 may be a secondary battery, such as a nickel metal hydride battery and a lithium ion battery. Instead of the secondary battery, an electric double layer capacitor may be used.

The number of the single cells 10 may be set as needed on the basis of a required output of the battery pack 100, and the like. In the battery pack 100 according to the present embodiment, all the single cells 10 are connected in series with one another. Instead, the battery pack 100 may include a plurality of single cells 10 connected in parallel with each other.

A monitoring unit 200 detects the terminal voltage of the battery pack 100 or detects the terminal voltage of each of the single cells 10, and then outputs the detected result to an electronic control unit (ECU) 300.

A temperature sensor 201 detects the temperature of the battery pack 100 (single cells 10), and outputs the detected result to the ECU 300. Here, the temperature sensor 201 may be provided at one location on the battery pack 100 or may be provided at mutually different multiple locations on the battery pack 100. When the temperatures respectively detected by the plurality of temperature sensors 201 are different from each other, a median value of the plurality of detected temperatures may be, for example, used as the temperature of the battery pack 100.

A current sensor 202 detects a current flowing through the battery pack 100, and outputs the detected result to the ECU 300. In the present embodiment, a current value detected by the current sensor 202 is a positive value when the battery pack 100 is discharged. A current value detected by the current sensor 202 is a negative value when the battery pack 100 is charged.

In the present embodiment, the current sensor 202 is provided in a positive electrode line PL connected to a positive electrode terminal of the battery pack 100; however, the current sensor 202 just needs to be able to detect a current flowing through the battery pack 100. A location at which the current sensor 202 is provided may be set as needed. For example, the current sensor 202 may be provided in a negative electrode line NL connected to a negative electrode terminal of the battery pack 100. A plurality of the current sensors 202 may be used.

The ECU (which corresponds to a controller) 300 includes a memory 301. The memory 301 stores various pieces of information with which the ECU 300 executes a predetermined process (for example, a process that will be described in the present embodiment). In the present embodiment, the memory 301 is incorporated in the ECU 300. Instead, the memory 301 may be provided outside the ECU 300.

A system main relay SMR-B is provided in the positive electrode line PL. The system main relay SMR-B switches between an on state and an off state upon reception of a control signal from the ECU 300. A system main relay SMR-G is provided in the negative electrode line NL. The system main relay SMR-G switches between an on state and an off state upon reception of a control signal from the ECU 300.

A system main relay SMR-P and a current limiting resistor 203 are connected in parallel with the system main relay SMR-G. Here, the system main relay SMR-P and the current limiting resistor 203 are connected in series with each other. The system main relay SMR-P switches between an on state and an off state upon reception of a control signal from the ECU 300. The current limiting resistor 203 is used to suppress flow of inrush current when the battery pack 100 is connected to a load (specifically, an inverter 204 (described later)).

When the battery pack 100 is connected to the inverter 204, the ECU 300 initially switches the system main relay SMR-B from the off state to the on state, and switches the system main relay SMR-P from the off state to the on state. Thus, current flows through the current limiting resistor 203.

Subsequently, after the ECU 300 switches the system main relay SMR-G from the off state to the on state, the ECU 300 switches the system main relay SMR-P from the on state to the off state. Thus, connection between the battery pack 100 and the inverter 204 is completed, and the battery system shown in FIG. 1 enters an activated state (ready-on state). Information about the on/off state (IG-ON/IG-OFF) of an ignition switch of the vehicle is input to the ECU 300, and the ECU 300 starts up the battery system in response to switching of the ignition switch from the off state to the on state.

On the other hand, when the ignition switch switches from the on state to the off state, the ECU 300 switches the system main relays SMR-B, SMR-G from the on state to the off state. Thus, connection between the battery pack 100 and the inverter 204 is interrupted, and the battery system enters a stopped state (ready-off state).

The inverter 204 converts direct-current power, output from the battery pack 100, to alternating-current power, and outputs the alternating-current power to a motor generator 205. The motor generator 205 may be, for example, a three-phase alternating-current motor. The motor generator 205 generates kinetic energy for propelling the vehicle upon reception of the alternating-current power output from the inverter 204. The kinetic energy generated by the motor generator 205 is transmitted to wheels, and is able to propel the vehicle.

When the vehicle is decelerated or stopped, the motor generator 205 converts kinetic energy, generated at the time of braking the vehicle, to electric energy (alternating-current power). The inverter 204 converts the alternating-current power, generated by the motor generator 205, to direct-current power, and outputs the direct-current power to the battery pack 100. Thus, the battery pack 100 is able to store regenerated electric power.

In the present embodiment, the battery pack 100 is connected to the inverter 204; however, the invention is not limited to this configuration. Specifically, the battery pack 100 may be connected to a step-up circuit, and the step-up circuit may be connected to the inverter 204. It is possible to step up the output voltage of the battery pack 100 with the use of the step-up circuit. The step-up circuit is also able to step down the output voltage from the inverter 204 to the battery pack 100.

A charger 206 is connected to the positive electrode line PL and the negative electrode line NL. Specifically, the charger 206 is connected to the positive electrode line PL that connects the system main relay SMR-B to the inverter 204, and is connected to the negative electrode line NL that connects the system main relay SMR-G to the inverter 204. An inlet (connector) 207 is connected to the charger 206.

A charging relay Rch1 is provided in a line that connects the charger 206 to the line PL. A charging relay Rch2 is provided in a line that connects the charger 206 to the line NL. The charging relays Rch1, Rch2 switch between an on state and an off state upon reception of control signals from the ECU 300.

A charging plug (connector) extended from an external power supply 208 is connected to the inlet 207. By connecting the charging plug to the inlet 207, it is possible to supply electric power, supplied from the external power supply 208, to the battery pack 100 via the charger 206. Thus, it is possible to charge the battery pack 100 with the use of the external power supply 208. When the external power supply 208 supplies alternating-current power, the charger 206 converts alternating-current power, supplied from the external power supply to direct-current power, and supplies the direct-current power to the battery pack 100. The ECU 300 is able to control the operation of the charger 206.

When electric power from the external power supply 208 is supplied to the battery pack 100, the charger 206 is able to convert voltage. Here, charging the battery pack 100 with electric power supplied from the external power supply 208 to the battery pack 100 is termed external charging. In the battery system according to the present embodiment, when the charging relays Rch1, Rch2 and the system main relays SMR-B, SMR-G are in the on state, electric power from the external power supply 208 is supplied to the battery pack 100. When external charging is carried out, it is possible to supply a constant current to the battery pack 100, and it is possible to charge the battery pack 100 at a constant current.

A system of supplying electric power from the external power supply 208 to the battery pack 100 is not limited to the system shown in FIG. 1. For example, the charger 206 may be connected to the battery pack 100 without intervening the system main relays SMR-B, SMR-P, SMR-G. Specifically, the charger 206 may be connected via the charging relay Rch1 to the positive electrode line PL that connects the battery pack 100 to the system main relay SMR-B and may be connected via the charging relay Rch2 to the negative electrode line NL that connects the battery pack 100 to the system main relay SMR-G. In this case, it is possible to carry out external charging by switching the charging relays Rch1, Rch2 from the off state to the on state.

In the present embodiment, external charging is carried out by connecting the charging plug to the inlet 207; however, the invention is not limited to this configuration. Specifically, it is possible to supply electric power from the external power supply 208 to the battery pack 100 with the use of a so-called contactless charging system. In the contactless charging system, it is possible to supply electric power without intervening a cable by utilizing electromagnetic induction or a resonance phenomenon. A known configuration may be employed as the contactless charging system as needed.

In the present embodiment, the charger 206 is mounted on the vehicle; however, the invention is not limited to this configuration. That is, the charger 206 may be installed separately from the vehicle outside the vehicle. In this case, the ECU 300 is able to control the operation of the charger 206 through communication between the ECU 300 and the charger 206.

The ECU 300 is able to calculate (estimate) the SOC of the battery pack 100 on the basis of the voltage value detected by the monitoring unit 200, the battery temperature detected by the temperature sensor 201, and the current value detected by the current sensor 202, and is able to execute charging/discharging control over the battery pack 100 on the basis of the calculated SOC and a full charge capacity estimated value. The ECU 300 may be configured to include functions of an SOC estimating unit, a full charge capacity computing unit and an external charging control unit.

The SOC of the battery pack 100 indicates the percentage (state of charge) of the current charge amount to the full charge capacity of the battery pack 100, and the full charge capacity is an upper limit value of the SOC. The SOC is determined from the open circuit voltage (OCV) of the battery pack 100. For example, the correspondence relationship between the OCV and SOC of the battery pack 100 is stored in the memory 301 in advance as an OCV-SOC map. The ECU 300 is able to calculate the OCV of the battery pack 100 from the voltage (closed circuit voltage (CCV)) detected by the monitoring unit 200 and is able to calculate the SOC from the OCV-SOC map.

The correspondence relationship between the OCV and SOC of the battery pack 100 changes with the battery temperature. Therefore, it is applicable that the OCV-SOC map is stored in the memory 301 for each battery temperature in advance and then the SOC of the battery pack 100 is estimated by switching (selecting) the SOC-OCV map on the basis of the battery temperature at the time when the SOC is estimated from the OCV of the battery pack 100.

Thus, the ECU 300 is able to acquire an overcharged state or overdischarged state of the battery pack 100 by monitoring the voltage value (CCV) detected by the monitoring unit 200 during charging or discharging. For example, it is possible to execute charging/discharging control for limiting charging of the battery pack 100 such that the calculated SOC does not become higher than a predetermined upper limit SOC with respect to the full charge capacity or limiting discharging such that the calculated SOC does not become lower than a lower limit SOC.

The ECU 300 may be provided for each of the inverter 204 and the motor generator 205. An additional ECU for executing an SOC estimation process, a full charge capacity estimation process and an external charging process may be provided independently of vehicle control. That is, a central control unit that governs control over the entire vehicle may be configured to control components. Alternatively, an individual ECU may be provided for each control over a corresponding component, and a central control unit may be connected to each of the individual ECUs.

The full charge capacity of the battery pack 100 is allowed to be calculated on the basis of the following mathematical expression 1.

Full charge capacity=Accumulated current value (ΣI)÷(SOC_{—}e−SOC_{—}s)×100 (Mathematical Expression 1)

In the above mathematical expression 1, the full charge capacity is the full charge capacity of the battery pack 100 based on actually measured values of the monitoring unit 200, the current sensor 202, and the like. An SOC_s (initial SOC) is the SOC of the battery pack 100 at the time when accumulation of current is started in external charging. An SOC_e is the SOC of the battery pack 100 at the time when accumulation of current is terminated. The accumulated current value is a value obtained by accumulating an external charging current of the battery pack 100 in a period from when the SOC_s is calculated to when the SOC_e is calculated. A value obtained by subtracting the SOC_s from the SOC_e indicates a change (SOC difference=ΔSOC) in SOC between before and after external charging, and the full charge capacity of the battery pack 100 is allowed to be calculated from the percentage of the amount of current to a change in SOC.

A full charge capacity learning value is a learning value of the full charge capacity, which is calculated by using the full charge capacity that is calculated from an actually measured value, and is, for example, allowed to be calculated from the currently calculated full charge capacity and a last full charge capacity learning value as shown in the following mathematical expression 2.

Full charge capacity learning value=Last full charge capacity learning value×(1−K)+Full charge capacity×K (Mathematical Expression 2)

In the above mathematical expression 2, K is a reflection coefficient (learning parameter) that determines the ratio of the actually measured full charge capacity and the last full charge capacity learning value, included in the currently calculated full charge capacity learning value. K is a value within the range of 0 to 1, and the full charge capacity learning value is allowed to be calculated by applying a selected value.

As can be understood from the mathematical expression 2, the full charge capacity that is an actually measured full charge capacity acquired value is calculated on the basis of the SOC difference of the battery pack 100 and the accumulated current value, and the full charge capacity learning value is calculated by learning the full charge capacity each time the full charge capacity is calculated. The current (new) full charge capacity learning value is calculated by incorporating the last full charge capacity learning value and the latest (current) full charge capacity at a predetermined ratio. The ECU 300 is able to determine a vehicle range by using electric power from the battery pack 100 with the use of the full charge capacity learning value or determine the upper limit value and lower limit value of the SOC in charging/discharging control based on the SOC of the battery pack 100. A degradation state of the battery pack 100 (single cells 10) is allowed to be acquired from a change in the full charge capacity learning value.

The ECU 300 is able to store an SOC_s, an SOC_e, ΔSOC, an accumulated current value, a charging time, a full charge capacity, a full charge capacity learning value, and the like, in the memory 301 as a charging history. In the SOC estimation process according to the present embodiment, the terminal voltage of the battery pack 100 is detected by the monitoring unit 200 in a state immediately before or immediately after the battery pack 100 is connected to a load or the charger 206, the voltage value detected by the monitoring unit 200 is used as the OCV, and the SOC is calculated from the OCV-SOC map.

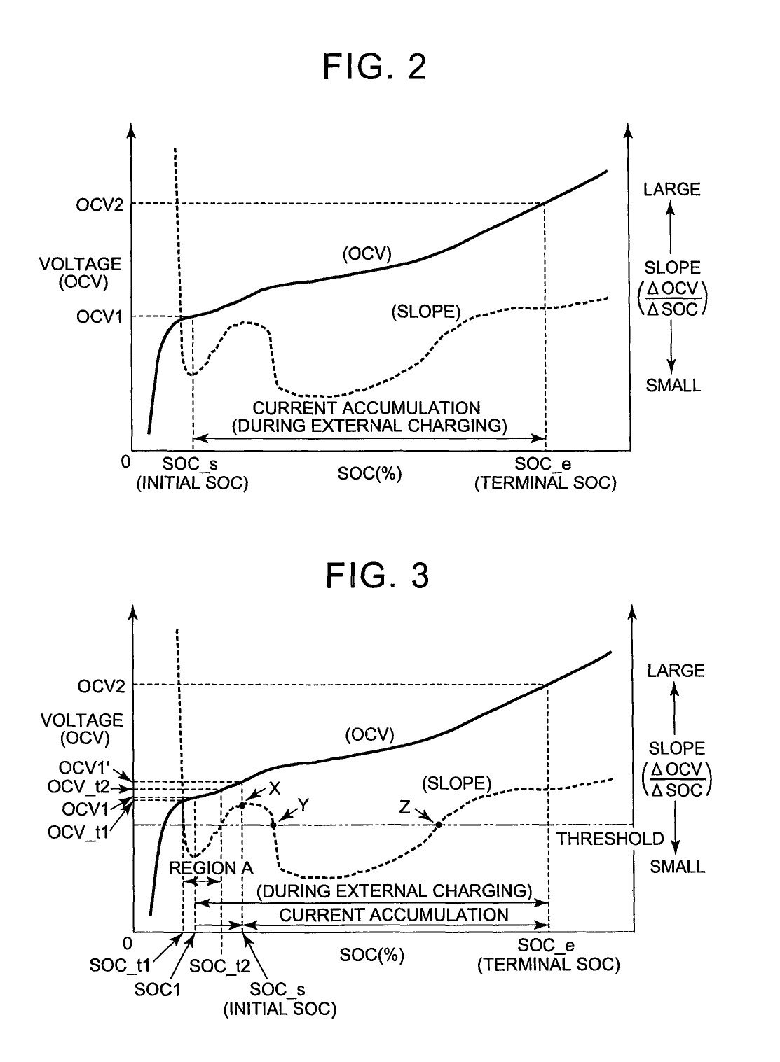

FIG. 2 is a view that shows an example of the OCV-SOC correspondence relationship (map) according to the present embodiment. The abscissa axis represents the SOC of the battery pack 100, the left ordinate axis represents the OCV corresponding to the battery pack 100, and the right ordinate axis represents the rate (slope) of a change in OCV with respect to a change in SOC.

As shown in FIG. 2, the ECU 300 executes the full charge capacity computing process together with external charging. The ECU 300 calculates the SOC at the charging start timing, at which the battery pack 100 is charged, from an OCV1, and stores the calculated SOC in the memory 301 as the SOC_s. After that, the process of accumulating a charging current flowing through the battery pack 100 is executed until the termination of charging. The ECU 300 monitors the voltage value of the battery pack 100, and then terminates charging and calculates the SOC after the termination of charging when the voltage value becomes a voltage value (OCV2) corresponding to the SOC upper limit value corresponding to the termination of charging. The SOC calculated after the termination of charging is stored in the memory 301 as the SOC_e.

As described above, the ECU 300 calculates the full charge capacity of the battery pack 100 on the basis of the SOC difference (SOC_e−SOC_s) between before and after external charging and the accumulated charging current value during charging. However, if it is not possible to accurately calculate the SOC, the accuracy of calculating the full charge capacity decreases.

For example, as shown in FIG. 2, the slope of the correspondence relationship (OCV curve) between an OCV and an SOC is not constant. That is, there are a region in which the rate of a change in OCV to a unit change in SOC (the rate of change in voltage for a change in SOC) is large and a region in which the rate of a change in OCV to a unit change in SOC is small. In FIG. 2, the continuous line indicates an OCV curve for an SOC, and the dotted line indicates a slope (ΔOCV/ΔSOC) of the OCV curve. In the region in which the slope is small, the OCV curve is close to a horizontal line, and the OCV does not change so much even when the SOC changes, so the accuracy of calculating (estimating) the SOC decreases. In other words, in the region in which the SOC significantly changes with a small change in OCV, it is not possible to accurately calculate the SOC because of variations due to a voltage detection error, or the like, of the monitoring unit 200.

The OCV curve also changes because of degradation of the battery pack 100, so the SOC corresponding to the region in which the rate of a change in OCV for a change in SOC is small may not be accurately calculated on the basis of the OCV of the battery pack 100.

Therefore, when the SOC (corresponding OCV1) that is calculated at the start of external charging is the SOC corresponding to the region in which the slope of the OCV curve is small, if the calculated SOC is directly used as the SOC_s, it is not possible to accurately calculate the full charge capacity.

In the present embodiment, when the SOC that is calculated at the start of external charging is the SOC corresponding to the region in which the slope of the OCV curve is smaller than a predetermined value, in other words, when the calculated SOC corresponds to the region in which the rate of a change in OCV for a change in SOC is smaller than the predetermined value, the initial SOC for calculating the full charge capacity is calculated after the SOC is shifted by external charging from the region in which the slope of the OCV curve is small to the region in which the slope is large.

In this way, in the full charge capacity computing process associated with external charging, the initial SOC is variably controlled, the initial SOC (SOC_s) is estimated in the region in which the accuracy of estimating the SOC is ensured by avoiding the region in which it is recognized in advance that the accuracy of calculating the SOC decreases in the OCV-SOC map, and the accuracy of calculating the full charge capacity is improved.

FIG. 3 is a graph that shows an example in which the initial SOC is variably calculated for the slope of the OCV curve in the OCV-SOC map according to the present embodiment.

As shown in FIG. 3, it is possible to set a predetermined threshold for the slope of the OCV curve of the OCV-SOC map, and to determine the SOC (corresponding OCV) corresponding to the region in which the slope is smaller than the threshold. The threshold may be, for example, set as needed on the basis of a voltage detection error, or the like, of the monitoring unit 200 and the rate of a change in OCV for a change in SOC. In consideration of a voltage detection error of the monitoring unit 200, when the rate of a change in OCV for a change in SOC is large, a value above which predetermined SOC estimation accuracy is ensured (when the rate of a change in OCV for a change in SOC is small, a value below which predetermined SOC estimation accuracy is not ensured) is arbitrarily set as the threshold.

In the example of the OCV curve shown in FIG. 3, because a slope corresponding to the range of an SOC_t1 to an SOC_t2 is smaller than the threshold, a region A in which the slope is smaller than the threshold is allowed to be set as a region in which SOC estimation accuracy is not ensured. It appears that, between the SOC_t1 and the SOC_t2, a corresponding change from an OCV_t1 to an OCV_t2 is small and, therefore, it is not possible to accurately calculate the SOC because of a voltage detection error of the monitoring unit 200.

As shown in FIG. 3, the ECU 300 calculates the SOC (which corresponds to a first SOC) of the battery pack 100 at the start of external charging. It is determined whether the calculated SOC1 is higher than the SOC_t1 and lower than the SOC_t2 (whether the calculated SOC1 corresponds to the SOC corresponding to the region A). When SOC_t1<SOC1<SOC_t2, the SOC1 is set as the initial SOC, and supply of charging current to the battery pack 100 is started without executing the charging current accumulation process.

The SOC1 of the battery pack 100 corresponding to the region A increases with the charging current supplied, exceeds the SOC_t2, and shifts to the SOC corresponding to the region in which the slope is larger than the threshold. The SOC shifted from the region A in which the slope is smaller than the threshold to the region in which the slope is large ensures predetermined SOC calculation accuracy. Therefore, the ECU 300 calculates the SOC (which corresponds to a second SOC) of the battery pack 100 at the time when the battery pack 100 is changed to the SOC corresponding to the region in which the slope (rate of change) of the OCV curve is larger than the threshold as the initial SOC, starts the charging current accumulation process from the state where the battery pack 100 is charged to the SOC corresponding to the region in which the slope of the OCV curve is larger than the threshold, and executes the accumulation process until the termination of charging. The ECU 300 calculates the SOC of the battery pack 100 at the termination of charging (terminal SOC).

As described above, when the SOC avoids the region A and corresponds to the region in which the slope of the OCV curve is larger than the threshold, the predetermined SOC calculation accuracy is ensured. Therefore, the ECU 300 is able to execute control such that the SOC at the time when the SOC corresponding to the region A becomes a value higher than the SOC_t2 is set for the initial SOC and the charging current accumulation process is started. However, for example, as shown in FIG. 3, the OCV curve of the OCV-SOC map is defined in advance, so the SOC (X point indicated by the black circle in FIG. 3) at which the slope of the OCV curve is maximum is allowed to be recognized in the region in which the slope of the OCV curve adjacent to the region A is larger than or equal to the threshold.

In the present embodiment, the SOC corresponding to the maximum rate of change of the OCV curve, which is adjacent to the region A and is larger than or equal to the threshold, is set in advance, the SOC1 of the battery pack 100, corresponding to the region A, is increased by charging current supplied, and is shifted beyond the SOC_t2 to a predetermined SOC (SOC corresponding to the slope at point X) corresponding to the maximum slope of the region in which the slope is larger than the threshold. With such a configuration, it is possible to further increase the SOC calculation accuracy, and it is possible to further accurately calculate the full charge capacity.

In the example of FIG. 3, in the range in which the SOC is higher than the SOC_t2 in the direction in which the SOC increases from the region A, there is a region in the OCV curve in which the slope is smaller than the threshold. Therefore, when the SOC1 of the battery pack 100, which is calculated at the start of external charging, is the SOC corresponding to a slope from point Y to point Z, indicated by the black circles in FIG. 3, the SOC1 of the battery pack 100 is allowed to be increased by charging current supplied to be shifted to the SOC corresponding to the region in which the slope is larger than or equal to the threshold after point Z.

Because the range from point Y to point Z, indicated by the black circles in FIG. 3, is wide, if the SOC1 of the battery pack 100 is increased by charging current supplied to be shifted to the SOC corresponding to the region in which the slope is larger than or equal to the threshold after point Z, an initial SOC is close to the terminal SOC, so the SOC difference for calculating the full charge capacity reduces.

When the SOC difference is small, the amount of electric power that is charged to the battery pack 100, that is, the accumulated current value, also reduces. The accumulated current value contains a detection error of the current sensor 202. Therefore, if the accumulated current value is small, the ratio of the detection error included in the accumulated current value increases, and the accuracy of the full charge capacity may decrease.

In consideration of such a point, when the SOC1 of the battery pack 100, which is calculated at the start of external charging, is the SOC corresponding to the region A, the SOC1 is shifted to the SOC corresponding to the region in which the slope is larger than the threshold and then calculation of an initial SOC and the charging current accumulation process are started. When the SOC1 is the SOC in the region corresponding to the region from point Y to point Z, indicated by the black circles in FIG. 3, in which the slope is smaller than the threshold, the full charge capacity calculation process itself is not executed or the SOC is set for the initial SOC and the full charge capacity is calculated by using an accumulated charging current value from the charging start timing. Instead, as will be described later, it is possible to execute control such that the amount of incorporation in the full charge capacity learning value is reduced or not incorporated.

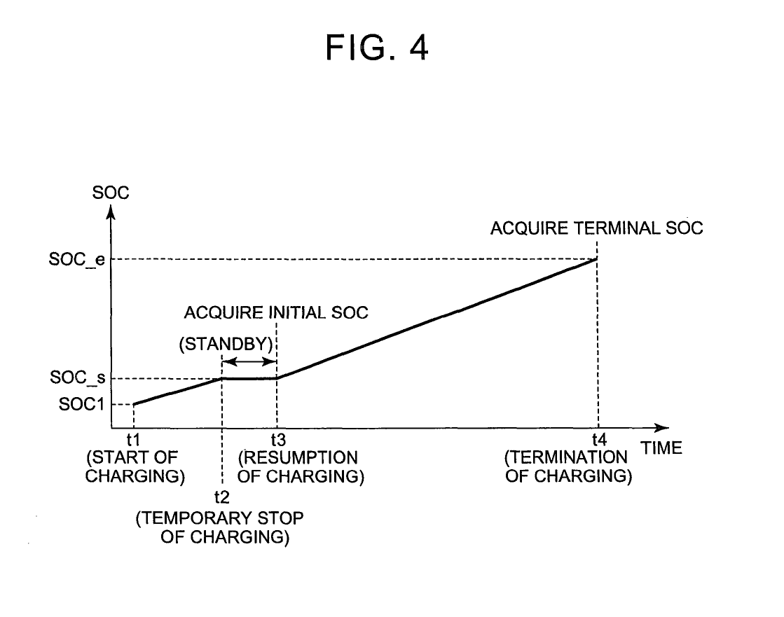

FIG. 4 is a graph for illustrating external charging control in which the initial SOC is variable. As shown in FIG. 4, initially, at the start of charging, an SOC before charging current is supplied to the battery pack 100 (before charging) is calculated. The ECU 300 carries out charging by starting supply of electric power from the external power supply 40 to the battery pack 100 from time t1.

At this time, the ECU 300 determines whether the calculated pre-charging SOC is the SOC (or OCV) corresponding to the region in which the slope of the OCV curve is smaller than the threshold. When the calculated pre-charging SOC is the SOC corresponding to the region in which the slope of the OCV curve is smaller than the threshold, the ECU 300 monitors the SOC (OCV) that increases through charging, continues charging until the SOC becomes the SOC corresponding to the region in which the slope of the OCV curve is larger than or equal to the threshold, and temporarily stops charging when the SOC has reached a predetermined SOC corresponding to the region in which the slope of the OCV curve is larger than or equal to the threshold (time t2).

The ECU 300 enters a standby state from time t2 at which charging is temporarily stopped, and calculates the SOC of the battery pack 100 at the time when the battery pack 100 has been charged to the SOC corresponding to the region in which the slope of the OCV curve is larger than the threshold at time t3 after a lapse of a predetermined period of time from time t2. A standby time between time t2 and time t3 is, for example, a period of time set in advance in order to resolve polarization of the battery pack 100 due to charging. An accurate SOC is allowed to be calculated by acquiring an OCV after a lapse of the predetermined period of time from a temporary stop of charging.

The ECU 300 resumes charging from time t3, carries out charging until time t4, that is the termination of charging from the state at time t3 at which charging is resumed (state in which the battery pack 100 has been charged to the SOC corresponding to the region in which the slope of the OCV curve is larger than the threshold), and executes the process of accumulating a charging current between time t3 and time t4 by excluding a charging current from time t1 to time t2. The ECU 300 calculates a post-charging SOC (which corresponds to a third SOC) at time t4 or after a lapse of a predetermined period of time from time t4.

The accumulated charging current value between time t3 and time t4 may also be obtained by subtracting a value, obtained by accumulating a current from time t1 to time t2, from an accumulated current value from time t1 at which charging current is supplied to the battery pack 100 to time t4 at the termination of charging. In this case, the current accumulation process is allowed to be started from time t1. Thus, the timing at which the current accumulation process is started may be fixed to time t1 (the start of charging) irrespective of whether the SOC of the battery pack 100 corresponds to the region in which the slope of the OCV curve is smaller than the threshold or corresponds to the region in which the slope of the OCV curve is larger than the threshold.

In this way, in the full charge capacity calculation method according to the present embodiment, when the SOC calculated at the start of charging is the SOC corresponding to the region in which the slope of the OCV curve is smaller than the threshold, the battery pack 100 is charged until the SOC of the battery pack 100 becomes the SOC corresponding to the region in which the slope of the OCV curve in the OCV-SOC correspondence relationship becomes the SOC corresponding to the region in which the slope is larger than the threshold. The full charge capacity is then calculated on the basis of the accumulated charging current value from the state where the battery pack 100 has been charged to the SOC corresponding to the region in which the slope is larger than the threshold to the termination of charging, and the SOC difference between the SOC at the time when the battery pack 100 has been charged to the SOC corresponding to the region in which the slope is larger than the predetermined value and the SOC calculated at the termination of charging. Therefore, it is possible to accurately calculate the SOC by avoiding calculation of the SOC in a region in which a change in OCV is small for a change in SOC, so it is possible to improve the accuracy of calculating the full charge capacity.

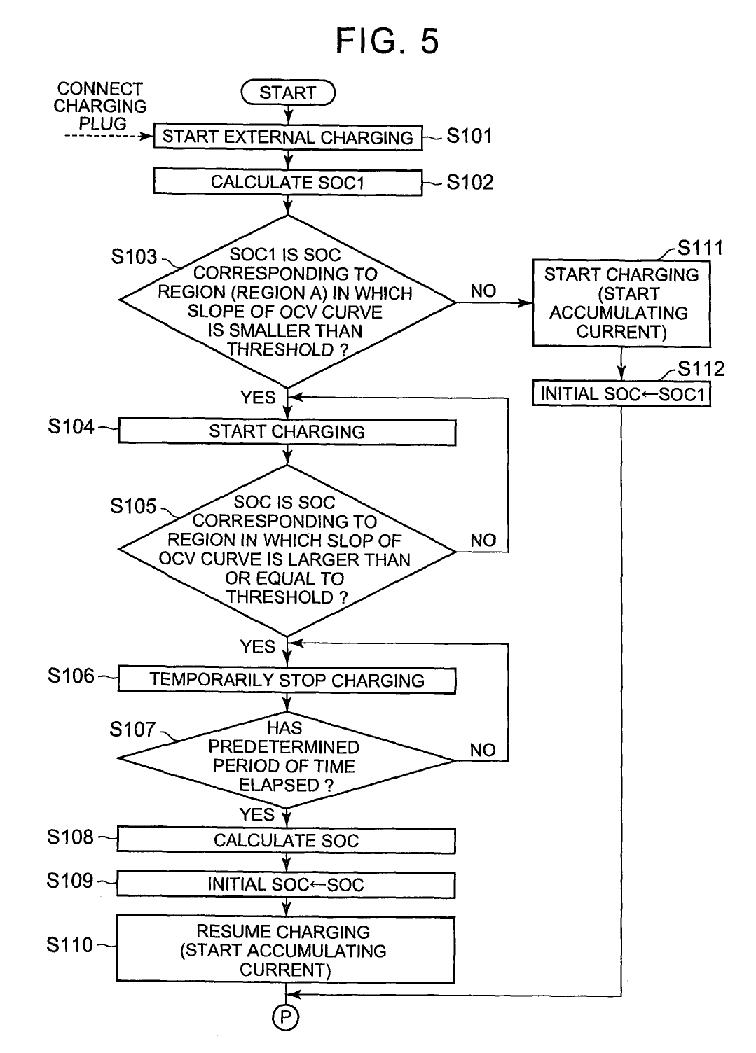

FIG. 5 is a flowchart that shows an external charging operation in which the battery system according to the present embodiment is charged from the external power supply 208. The external charging operation is carried out by the ECU 300. At this time, the system main relays SMR-B, SMR-G, SMR-P and the charging relays Rch1, Rch2 are in the off state.

When the ECU 300 has detected that the connection plug extended from the external power supply 208 has been connected to the inlet 207, the ECU 300 connects the charger 206 to the battery pack 100 by switching the charging relays Rch1, Rch2 from the off state to the on state, thus starting external charging via the charger 206 (S101).

In step S102, the ECU 300 acquires a voltage (OCV1) via the monitoring unit 200, and calculates a pre-charging SOC1. The pre-charging SOC1 is stored in the memory 301. In step S103, the ECU 300 determines whether the SOC1 is the SOC in the region in which the slope of the OCV curve is smaller than the threshold (region A: SOC_t1<SOC<SOC_t2).

When the ECU 300 has determined in step S103 that the SOC1 is the SOC in the region in which the slope of the OCV curve is smaller than the threshold, the ECU 300 proceeds with the process to step S104, and charges the battery pack 100 at a predetermined charging current by outputting a control signal to the charger 206.

The charger 206 controls the charging current on the basis of the control signal from the ECU 300. For example, a control value for the charging current is output to the charger 206 in accordance with a predetermined charging current value, and the charger 206 tunes (AC/DC conversion, stepping up, or the like) current that is supplied from the external power supply 208, and outputs charging current to the battery pack 100.

When the ECU 300 has determined that the SOC1 is the SOC in the region in which the slope of the OCV curve is smaller than the threshold, the ECU 300 monitors the SOC (OCV) that increases through charging and continues charging until the SOC becomes the SOC corresponding to the region in which the slope of the OCV curve becomes larger than or equal to the threshold (S105). The ECU 300 temporarily stops charging when the SOC has reached the predetermined SOC corresponding to the region in which the slope of the OCV curve is larger than or equal to the threshold (S106).

The ECU 300 enters a standby state for a predetermined period of time from the timing at which charging has been temporarily stopped (S107). After a lapse of the predetermined period of time, the ECU 300 calculates the SOC of the battery pack 100 at the time when the battery pack 100 has been charged to the SOC corresponding to the region in which the slope of the OCV curve is larger than the threshold (S108).

In step S109, the ECU 300 stores the SOC of the battery pack 100 at the time when the battery pack 100 has been charged to the SOC corresponding to the region in which the slope of the OCV curve is larger than the threshold, calculated in step S108, in the memory 301 as the initial SOC.

The ECU 300 calculates the SOC of the battery pack 100 after a lapse of the predetermined period of time from the temporary stop of charging, and then resumes charging and starts the process of accumulating a charging current that is detected by the current sensor 202 in step S110.

On the other hand, when the ECU 300 has determined in step S103 that the SOC1 is not the SOC in the region in which the slope of the OCV curve is smaller than the threshold, in other words, the SOC1 is the SOC in the region in which the slope of the OCV curve is larger than or equal to the threshold, the ECU 300 proceeds with the process to step S111, and charges the battery pack 100 at a predetermined charging current by outputting a control signal to the charger 205 and starts the process of accumulating the charging current that is detected by the current sensor 202. In step S112, the ECU 300 stores the SOC1 in the memory 301 as the initial SOC.

In the present embodiment, when the SOC1 is the SOC corresponding to the region in which the slope of the OCV curve is large, it is determined that it is possible to accurately calculate the initial SOC for calculating the full charge capacity, and charging is continued until the termination of charging without a temporary, stop of charging. Therefore, it is possible to reduce a charging time and to quickly calculate a highly accurate full charge capacity.

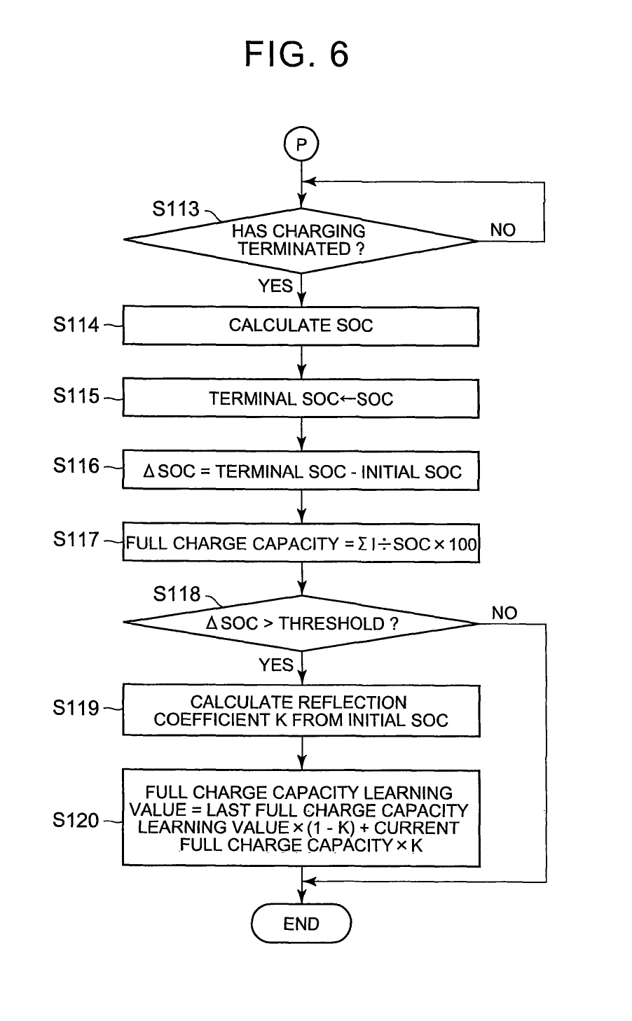

FIG. 6 is a flowchart that shows the external charging operation subsequent to FIG. 5, and is a view that shows the flow of the process of computing a post-charging full charge capacity and a full charge capacity learning value.

The ECU 300 monitors the voltage of the battery pack 100, which increases with a lapse of charging time, through the monitoring unit 200, and determines whether the monitored voltage has reached a voltage corresponding to a predetermined target SOC (SOC upper limit value) corresponding to the termination of charging (S113). When the monitored voltage has not reached the target SOC, the ECU 300 continues charging.

When the ECU 300 has determined in step S113 that the monitored voltage has reached the voltage corresponding to the predetermined target SOC, the ECU 300 ends charging control. The ECU 300 outputs a control signal for termination of charging to the charger 206, ends the charging current accumulation process, and stores the accumulated charging current value in the memory 301. The ECU 300 switches the charging relays Rch1, Rch2 from the on state to the off state to interrupt connection between the charger 206 and the battery pack 100.

In step S114, the ECU 300 acquires the voltage (OCV2) of the battery pack 100 after the termination of charging from the monitoring unit 200. At this time, after a lapse of a predetermined period of time from the timing of the termination of charging as in the case of step S107, the voltage of the battery pack 100 after the termination of charging is allowed to be acquired.

In step S115, the ECU 300 calculates the SOC of the battery pack 100 after the termination of charging on the basis of the voltage acquired in step S114. The ECU 300 stores the calculated SOC in the memory 301 as the terminal SOC. The charging history that is stored in the memory 301 at this timing includes the charging time, the accumulated charging current value, the initial SOC, the terminal SOC, and the like, and the pre-charging SOC1.

The ECU 300 calculates the full charge capacity and the full charge capacity learning value at the termination of external charging. The process of calculating the full charge capacity and the full charge capacity learning value may also be separately executed from the external charging process, and may be executed at any timing after the termination of external charging.

In step S116, the ECU 300 calculates the SOC difference (ΔSOC) between before and after charging for calculating the full charge capacity by using the initial SOC and the terminal SOC.

In step S117, the ECU 300 calculates the full charge capacity like the above-described mathematical expression 1 by using the calculated SOC difference and the accumulated charging current value during charging, accumulated from the timing corresponding to the initial SOC. The calculated full charge capacity and SOC difference are stored in the memory 301.

In step S118, the ECU 300 determines whether the SOC difference calculated in step S116 is larger than a predetermined value, as a condition for calculating the full charge capacity learning value. This is because, as described above, the ratio of a detection error of the current sensor 202, or the like, included in the accumulated current value increases with a reduction in the SOC difference and, therefore, there is a concern that the accuracy of the full charge capacity decreases. When the SOC difference between before and after charging for calculating the full charge capacity is larger than the predetermined value, the full charge capacity learning value that incorporates the calculated full charge capacity is calculated, and a certain level of accuracy of calculating the full charge capacity learning value is ensured.

In step S118, when the SOC difference is smaller than the predetermined value, the ECU 300 ends the process without calculating the full charge capacity learning value. On the other hand, when the SOC difference is larger than the predetermined value, the ECU 300 proceeds with the process to step S119, and calculates the full charge capacity learning value.

The ECU 300 calculates a reflection coefficient K in step S119 at the time of calculating a current (latest) full charge capacity learning value like the above-described mathematical expression 2.

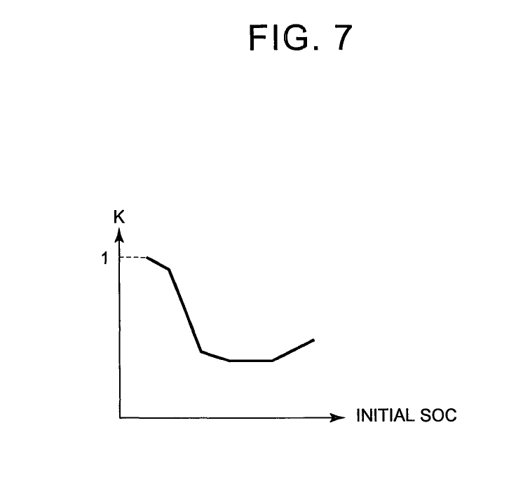

FIG. 7 is a graph that shows an example of calculating a reflection coefficient that is used to calculate the full charge capacity learning value. As shown in FIG. 7, the reflection coefficient K according to the present embodiment is calculated on the basis of the initial SOC obtained in order to calculate the full charge capacity.

Specifically, the value of the reflection coefficient K is allowed to be set on the basis of the slope (rate of change) of the OCV curve in the OCV-SOC correspondence relationship. As described above, when the initial SOC is the SOC corresponding to the region in which the slope of the OCV curve is small, the accuracy of calculating the initial SOC is low, so the accuracy of calculating the full charge capacity is also low. On the other hand, when the initial SOC is the SOC corresponding to the region in which the slope of the OCV curve is large, the accuracy of calculating the initial SOC is high, so the accuracy of calculating the full charge capacity is also high.

In the present embodiment, the reflection coefficient K is set on the basis of the slope of the OCV curve, associated with the accuracy of calculating the full charge capacity, is set in the following manner. When the accuracy of calculating the full charge capacity is high, the reflection coefficient K is increased, and the amount of incorporation in the full charge capacity learning value is also increased. On the other hand, when the accuracy of calculating the full charge capacity is low, the reflection coefficient K is decreased, and the amount of incorporation in the full charge capacity learning value is also reduced. The reflection coefficient K is calculated on the basis of the initial SOC.

In step S120, the ECU 300 acquires the full charge capacity calculated in step S117, the reflection coefficient K calculated in step S119, and the last full charge capacity learning value stored in the memory 301, and calculates the current full charge capacity learning value on the basis of the above-described mathematical expression 2. At this time, when the last full charge capacity learning value is not stored in the memory 301 (for example, the first external charging from the initial state), the current full charge capacity learning value is allowed to be calculated by using the initial full charge capacity (initial value) stored in the memory 301 in advance. The ECU 300 stores the calculated current full charge capacity learning value in the memory 301, and ends the process.

At the time of calculating the full charge capacity learning value in this way, the accuracy of calculating the full charge capacity is determined on the basis of the slope of the SOC difference in the OCV curve at the initial SOC, which is used to calculated the full charge capacity, the amount of incorporation in the full charge capacity learning value is increased when the calculation accuracy is high, and the amount of incorporation is reduced when the accuracy is low. Therefore, it is possible to improve the accuracy of calculating the full charge capacity learning value.

In the above description, when the SOC corresponding to the maximum rate of change of the OCV curve, which is adjacent to the region A and is larger than or equal to the threshold, is set in advance, the reflection coefficient K is allowed to be acquired in advance from the correlation between the initial SOC and the reflection coefficient K, shown in FIG. 7. Therefore, it is possible to configure the ECU 300 such that the ECU 300 calculates the full charge capacity learning value by using the predetermined reflection coefficient K. On the other hand, when the SOC corresponding to a specific rate of change larger than or equal to the threshold is not set for the region A in advance, the reflection coefficient K is calculated from the map shown in FIG. 7 on the basis of each SOC (initial SOC) corresponding to the rate of change larger than or equal to the threshold, so it is possible to calculate the full charge capacity learning value.

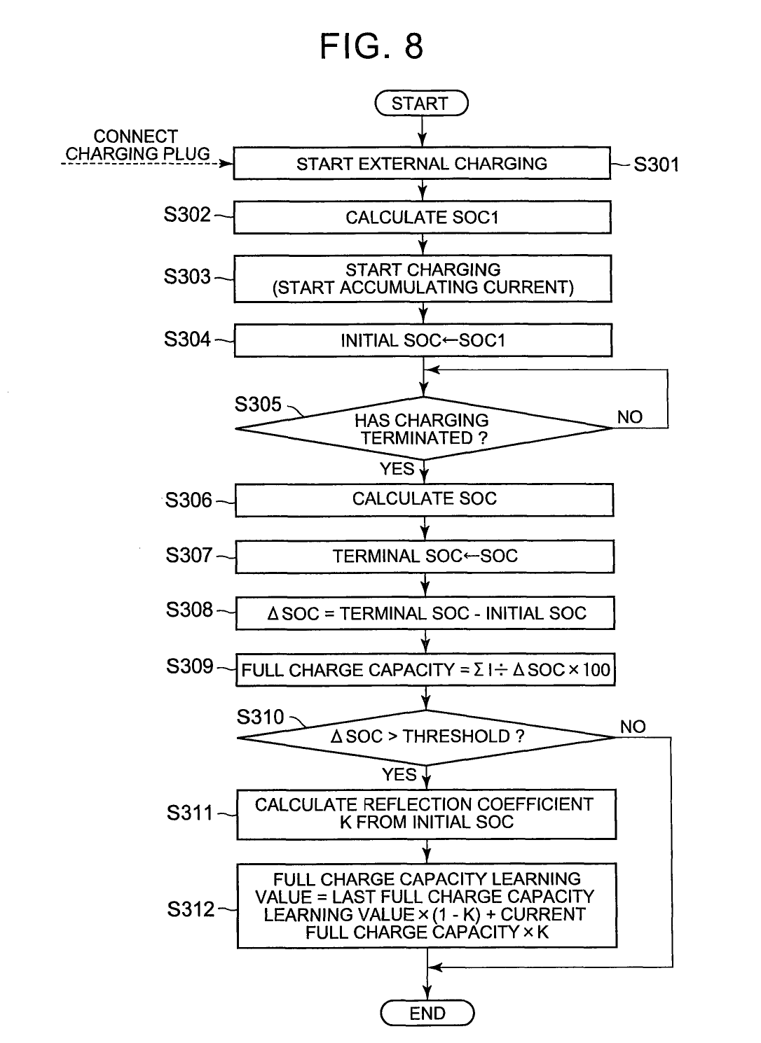

FIG. 8 is a flowchart that shows the charging operation of the battery system with the use of the external power supply and the process of computing a full charge capacity and a full charge capacity learning value according to an alternative embodiment.

In the above-described embodiment, the full charge capacity is accurately calculated by improving the SOC calculation accuracy. In terms of calculating the full charge capacity learning value, it is possible to acquire the SOC calculation accuracy, that is, the accuracy of calculating the full charge capacity, by using the initial SOC.

Therefore, in consideration of the fact that the SOC calculation accuracy decreases when the slope of the OCV curve is small and, as a result, it is not possible to accurately calculate the full charge capacity, it is possible to accurately calculate the full charge capacity learning value by changing the amount of incorporation of the calculated full charge capacity, which is incorporated in a new full charge capacity learning value, on the basis of the slope (rate of change) of the OCV curve corresponding to the initial SOC.

In the alternative embodiment shown in FIG. 8, not the process of calculating the full charge capacity is executed after the battery pack 100 is charged until the SOC of the battery pack 100 becomes the SOC corresponding to the region in which the slope of the OCV curve is higher than the threshold on the basis of the slope but the amount of incorporation of the calculated full charge capacity is changed on the basis of the rate of change of the OCV curve corresponding to the initial SOC at the time of calculating the full charge capacity learning value. That is, at the time of calculating the full charge capacity learning value, the accuracy of calculating the full charge capacity is acquired from the rate of change of the OCV curve corresponding to the initial SOC, and the amount of incorporation in the full charge capacity learning value is changed, thus making it possible to accurately calculate the full charge capacity learning value.

Among the steps in FIG. 8, step S301 to step S304 correspond to step S101, step S102, step S111 and step S112 in FIG. 5, and step S305 to step S312 respectively correspond to the steps shown in FIG. 6. In the alternative embodiment shown in FIG. 8, the reflection coefficient K may be derived from the reflection coefficient map shown in FIG. 7.

1. An electrical storage system mounted on a vehicle, comprising:
an electrical storage device configured to be charged or discharged; and
a controller configured to calculate an SOC on the basis of a correspondence relationship between a voltage of the electrical storage device and an SOC of the electrical storage device, the controller being configured to calculate a full charge capacity of the electrical storage device on the basis of an SOC difference between before and after charging and an accumulated charging current value during charging, wherein
when a first SOC that is calculated at start of charging is an SOC corresponding to a region in which a rate of change in voltage for a change in SOC is smaller than a predetermined value in the correspondence relationship, the controller is configured to execute control for charging the electrical storage device until the SOC of the electrical storage device changes from the first SOC to a second SOC corresponding to a region in which the rate of change in voltage for a change in SOC is larger than the predetermined value, and
the controller is configured to calculate the full charge capacity on the basis of an accumulated charging current value from a state where the electrical storage device has been charged to the second SOC to termination of charging and an SOC difference between the second SOC and a third SOC that is calculated at the termination of charging.

2. The electrical storage system according to claim 1, wherein
when the first SOC is the SOC corresponding to the region in which the rate of change in voltage for a change in SOC is larger than the predetermined value, the controller is configured to calculate the full charge capacity on the basis of an accumulated charging current value from a state of the first SOC to the termination of charging and an SOC difference between the first SOC and the third SOC.

3. The electrical storage system according to claim 1, wherein
when the first SOC is the SOC corresponding to the region in which the rate of change in voltage for a change in SOC is smaller than the predetermined value, the controller is configured to execute control for charging the electrical storage device until the SOC of the electrical storage device changes to an SOC corresponding to the maximum rate of change in the region in which the rate of change in voltage for a change in SOC is larger than the predetermined value, which is adjacent to the region in which the rate of change in voltage for a change in SOC is smaller than the predetermined value.

4. The electrical storage system according to claim 1, wherein
when the first SOC is the SOC corresponding to the region in which the rate of change in voltage for a change in SOC is smaller than the predetermined value, the controller is configured to execute control for temporarily stopping charging after the electrical storage device has been charged until the SOC of the electrical storage device changes from the first SOC to the SOC corresponding to the region in which the rate of change in voltage for a change in SOC is larger than the predetermined value, and
the controller is configured to calculate the second SOC after a lapse of a predetermined period of time from the temporary stop.

5. The electrical storage system according to claim 1, wherein
the controller is configured to learn the full charge capacity each time of charging, and is configured to calculate a new full charge capacity learning value by incorporating the full charge capacity in a previously calculated full charge capacity learning value, and the controller is configured to change an amount of incorporation of the full charge capacity that is incorporated in the new full charge capacity learning value, on the basis of the rate of change in voltage for a change in SOC in the correspondence relationship at an SOC that is used as an initial SOC of the SOC difference between before and after charging.

6. A full charge capacity estimation method for an electrical storage device mounted on a vehicle, comprising:
calculating each of an SOC before charging and an SOC after charging on the basis of a voltage of the electrical storage device and an SOC of the electrical storage device, and calculating an accumulated charging current value during charging;
calculating a full charge capacity on the basis of an SOC difference between before and after charging and the accumulated charging current value;
calculating a first SOC at start of charging at the time of calculating each of an SOC before charging and an SOC after charging on the basis of a voltage of the electrical storage device and an SOC of the electrical storage device, and calculating an accumulated charging current value during charging;
when the first SOC is an SOC corresponding to a region in which a rate of change in voltage for a change in SOC is smaller than a predetermined value in the correspondence relationship, charging the electrical storage device until the SOC of the electrical storage device changes from the first SOC to a second SOC corresponding to a region in which the rate of change in voltage for a change in SOC is larger than the predetermined value; and
calculating the full charge capacity on the basis of the accumulated charging current value from a state where the electrical storage device has been charged to the second SOC to termination of charging and an SOC difference between the second SOC and a third SOC that is calculated at the termination of charging.

7. An electrical storage system mounted on a vehicle, comprising:
an electrical storage device configured to be charged or discharged; and
a controller configured to calculate a full charge capacity of the electrical storage device on the basis of an SOC difference between before and after charging and an accumulated charging current value during charging, the controller being configured to learn the full charge capacity each time of charging and to calculate a new full charge capacity learning value by incorporating the calculated full charge capacity in a previously calculated full charge capacity learning value,
the controller being configured to change an amount of incorporation of the full charge capacity that is incorporated in the new full charge capacity learning value on the basis of a rate of change corresponding to an SOC that is used as an initial SOC of the SOC difference between before and after charging and the rate of change in voltage for a change in SOC in a correspondence relationship between a voltage of the electrical storage device and an SOC of the electrical storage device, which is used to calculate the SOC of the electrical storage device.
